(19) United States
(12) Patent Application Publication
(10) Pub. No.: US 2026/0262468 A1
(43) Pub. Date: Sep. 3, 2026

(54) CMP DEVICE AND WAFER TRANSFER METHOD

(71) Applicant: HANGZHOU SIZONE ELECTRONIC TECHNOLOGY INC., Zhejiang (CN)

(72) Inventors: Xiaoyu XU, Zhejiang (CN); Dongzhou ZHENG, Zhejiang (CN); Zhengting ZHU, Zhejiang (CN)

(73) Assignee: HANGZHOU SIZONE ELECTRONIC TECHNOLOGY INC., Zhejiang (CN)

(21) Appl. No.: 18/879,807

(22) PCT Filed: Jun. 30, 2023
(86) PCT No.: PCT/CN2023/104374

§ 371 Date: Dec. 30, 2024

(30) Foreign Application Priority Data
Jun. 30, 2022 (CN) 202210760423.8
Jun. 28, 2023 (CN) 202310776958.9

(51) Int. Cl. H10P 72/00; H10P 70/00; H10P 72/10; H10P 72/76

(52) U.S. Cl. CPC H10P 72/0472; H10P 72/0428; H10P 72/0456; H10P 72/0462; H10P 72/14; H10P 72/7602; H10P 72/7618; H10P 72/7624; H10P 70/20

(57) ABSTRACT

Disclosed is a CMP device, comprising: a polishing module; a cleaning module; and a cleaning input module, adjacent to the polishing module and the cleaning module and comprising a wafer transfer device; wherein, the wafer transfer device at least has a first operating state and a second operating state; in the first operating state, the wafer transfer device receives a wafer transferred from the polishing module, and the wafer is in a horizontal or approximately horizontal state; and in the second operating state, the wafer transfer device directly turns the wafer from the horizontal or approximately horizontal state to a vertical state. Further disclosed is a wafer transfer method. Integrated robot arm and transfer platform, wafer transfer between polishing module and cleaning module is achieved by wafer transfer device, simplified the intermediate transfer process and structure, and improved transfer efficiency; And it has a simple structure, and high transmission efficiency.

### TECHNICAL FIELD

The invention belongs to the technical field of fabrication of semiconductor integrated circuit chips, and particularly relates to a CMP device and a wafer transfer method.

### RELATED ART

A chemical mechanical planarization (CMP) device typically comprises a semiconductor equipment front end module (EFEM), a cleaning unit and a polishing unit. The EFEM mainly comprises a cassette for storing wafers, a robot arm for transferring wafers, an air purification system, and the like. The cleaning unit mainly comprises a varied number of megasonic cleaning components, roller brush cleaning components, drying components, devices for transferring wafers between the components, and the like. The polishing unit mainly comprises a polishing platen, a polishing head, a polishing liquid supply system, a polishing pad trimming system, and the like.

Wafer transfer between the polishing unit and other regions of an existing CMP device is implemented by a polishing transfer platform and a robot arm. The polishing transfer platform works together with the robot arm to transfer wafers out of or into the CMP device and functions as a bridge between a peripheral device and a key CMP part.

An existing double-claw robot arm has two claws and can grip two wafers at a time. It can take out a polished wafer and places in a wafer to be polished at the same time, then transfer the polished wafer to an input device of the cleaning unit, and fetch, from the EFEM, another wafer to be polished taken out of the cassette by an EFEM robot arm to enter the next cycle.

Because of the complex structure and low movement speed of the double-claw robot arm, the transfer efficiency is low, and the requirement for high-speed wafer transfer cannot be satisfied. In addition, the double-claw robot arm requires a humid operating environment and is expensive, difficult to manufacture and complex in structure, and the stability and reliability of the double-claw robot arm remain unverified.

In view of this, how to provide a wafer transfer device and method that can improve wafer transfer efficiency is a problem to be solved by those skilled in the art at present.

### SUMMARY OF INVENTION

To overcome the defects in the prior art, the invention provides a CMP device and a wafer transfer device. The CMP device has high wafer transfer efficiency, integrates a robot arm and a transfer platform, has a simple structure and requires a small transfer space.

The technical solution adopted by the invention to solve the abovementioned technical problems is as follows: A CMP device comprises:
a polishing module;
a cleaning module; and
a cleaning input module, adjacent to the polishing module and the cleaning module and comprising a wafer transfer device;
wherein, the wafer transfer device at least has a first operating state and a second operating state; in the first operating state, the wafer transfer device receives a wafer transferred from the polishing module, and the wafer is in a horizontal or approximately horizontal state; and in the second operating state, the wafer transfer device directly turns the wafer from the horizontal or approximately horizontal state to a vertical state.

Further, the cleaning input module further comprises a box, and after being switched to the vertical state, the wafer is temporarily stored in the box to wait to be transferred to the cleaning module by an external transfer device.

Further, the polishing module comprises a wafer transfer passage, and the wafer transfer device corresponds to the wafer transfer passage.

Further, the wafer transfer device comprises:
a back plate; and
a turning base plate, rotatably connected to the back plate and provided with a wafer fixing base for clamping the wafer;
the turning base plate has a first operating state and a second operating state;
in the first operating state, an included angle is formed between the turning base plate and the back plate, and the wafer fixing base clamps the wafer;
in the second operating state, the turning base plate rotates with respect to the back plate to switch the wafer to the vertical state.

Further, the back plate is able to ascend and descend along the box, and the box comprises an upper portion and a lower portion; in the first operating state, the turning base plate is located in the upper portion; and when switched from the first operating state to the second operating state, the turning base plate enters the lower portion.

Further, one, two or more wafer holders are arranged in the box and used for carrying the wafer in the vertical state from the turning base plate.

Further, the wafer fixing base comprises at least two support structures and a movable claw, and at least part of the movable claw is movable to work together with the support structures to clamp or release the wafer.

Further, each support structure comprises a body connected to the turning base plate, a first oblique surface arranged on the body, and a second oblique surface forming a flared opening with the first oblique surface.

Further, each support structure further comprises a third oblique surface, an included angle is formed between the third oblique surface and the second oblique surface, and the wafer is guided by the third oblique surface to a space between the first oblique surface and the second oblique surface to be clamped.

Further, a groove is formed between the first oblique surface and the second oblique surface.

Further, the cleaning module comprises at least two rows of cleaning units, and the box extends towards two sides to form a left portion and a right portion corresponding to the cleaning units.

Further, the wafer holder works together with a slide rail to move the wafer in the vertical state to a left portion or a right portion, and spraying mechanisms are arranged in the box.

The invention further discloses a wafer transfer method for the CMP device, comprising the following steps:
keeping the wafer transfer device in the first operating state, and transferring a wafer from the polishing module to the wafer transfer device;
directly turning the wafer transfer device from the first operating state to the second operating state, and temporarily storing the wafer in a vertical state in the box; and
transferring the wafer in the vertical state to the cleaning module.

Further, the wafer transfer method comprises the following steps:
keeping the turning base plate in the first operating state, and horizontally carrying and clamping the wafer by the wafer fixing base;
rotating the turning base plate with respect to the back plate to the second operating state to switch the wafer to the vertical state; and
allowing the back plate to descend drive the turning base plate and the wafer to descend.

Further, the wafer transfer method comprises the following steps:
keeping the turning base plate in the first operating state, horizontally transferring the wafer from the polishing module to the wafer fixing base, and clamping the wafer by the wafer fixing base, wherein the turning base plate is located in the box at this moment;
rotating the turning base plate with respect to the back plate to the second operating state to switch the wafer to the vertical state;
allowing the back plate to descend drive the turning base plate and the wafer to descend; and
transferring the wafer in the vertical state to the cleaning module.

Further, in the step of transferring the wafer in the vertical state to the cleaning module,
after a process of the cleaning input module is completed, the wafer is horizontally moved to the left portion or the right portion of the box and then transferred to the cleaning module in the vertical state.

The invention has the following benefits: (1) wafer transfer between the polishing module and the cleaning module is implemented by the wafer transfer device, a robot arm and a transfer platform are integrated, the step of transferring wafers by a robot arm in a humid environment is omitted, an intermediate transfer process is simplified, the transfer structure is simplified, and the transfer efficiency is higher; (2) the wafer transfer device can turn and move while clamping the wafer, thus fulfilling the function of a robot arm and being simple in structure, unlikely to break down and realize higher transfer efficiency; (3) the movement distance of the wafer transfer device is relatively shortened, transfer is more flexibly, and the transfer speed is higher; (4) the transfer speed is high, and faults are unlikely to occur; (5) wafers can be directly transferred by the wafer transfer device to the cleaning input module, and the wafer transfer device moves in a humid environment in the whole process to effectively prevent polishing liquid on the wafers from being evaporated, such that a negative influence on the wafers is avoided; (6) the wafer transfer device can directly transfer polished wafers to the cleaning module, and the step of transferring wafers by a robot arm in a humid environment is omitted, such that the wafers are prevented from being damaged in the transfer process; (7) the transfer space is relatively small; (8) the cleaning input module can quickly transfer wafers to a designated position, such that the wafer transfer efficiency is higher; (9) wafers can be placed into a cleaning tank closest to the cleaning input module by an external transfer device, such that transfer steps in the cleaning process are reduced; (10) the cleaning module may be provided with multiple rows of cleaning units to increase the cleaning speed.

### BRIEF DESCRIPTION OF DRAWINGS

FIG. 1 is a top view of a CMP device according to the invention.

FIG. 2 is a stereogram of the CMP device according to the invention.

FIG. 3 is a stereogram of a wafer transfer device in a case where a turning base plate is in a first operating state according to the invention.

FIG. 4 is a stereogram of the wafer transfer device in a case where the turning base plate is in a second operating state according to the invention.

FIG. 5 is a first stereogram of the wafer transfer device in a case where a support plate is arranged above the turning base plate according to the invention.

FIG. 6 is a second stereogram of the wafer transfer device in the case where a support plate is arranged above the turning base plate according to the invention.

FIG. 7 is a stereogram of a support structure according to the invention.

FIG. 8 is a stereogram of a box according to the invention.

FIG. 9 is a front view of the box according to the invention.

FIG. 10 is a top view of the box according to the invention.

FIG. 11 is a structural view of matching between the wafer transfer device and the box according to the invention.

### DESCRIPTION OF EMBODIMENTS

To allow those skilled in the art to gain a better understanding of the technical solutions of the invention, the technical solutions in the embodiments of the invention will be clearly and completely described below in conjunction with accompanying drawings of these embodiments. Obviously, the embodiments described below are merely illustrative ones, and are not all possible ones of the invention. All other embodiments obtained by those ordinarily skilled in the art based on the following ones without creative labor should also fall within the protection scope of the invention.

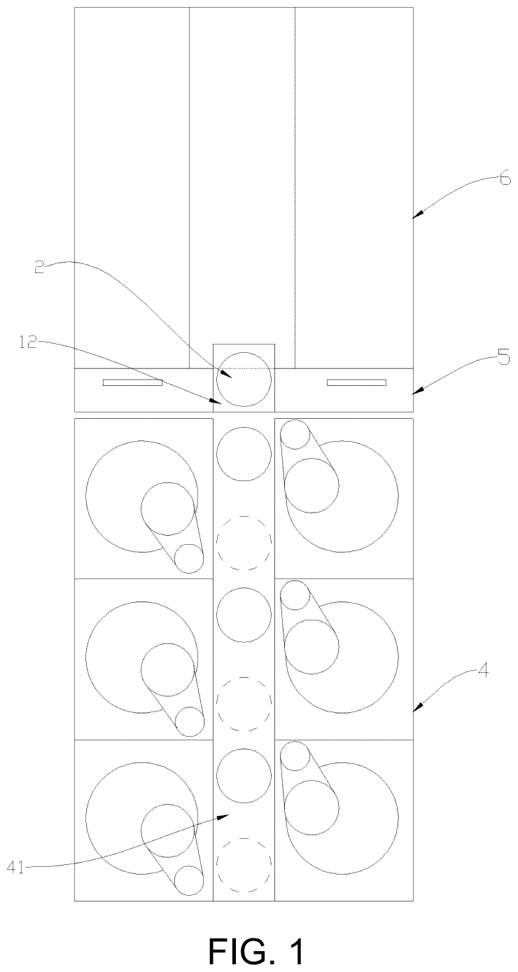

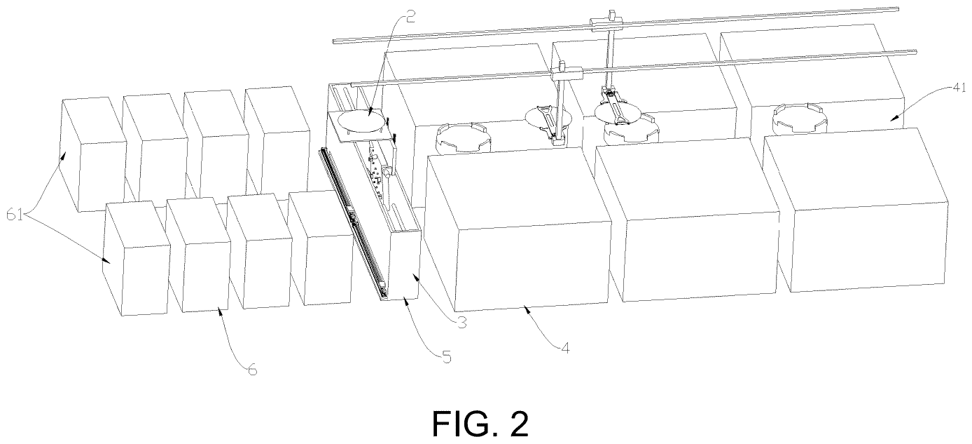

As shown in FIGS. 1 and 2, a CMP device comprises a polishing module 4, a cleaning input module 5 and a cleaning module 6, wherein the cleaning input module 5 is adjacent to the polishing module 4 and the cleaning module 6. In this embodiment, the polishing module 4, the cleaning input module 5 and the cleaning module 6 are arranged in sequence.

The cleaning input module 5 comprises a box 3 and a wafer transfer device 1, wherein the wafer transfer device 1 at least has a first operating state and a second operating state; in the first operating state, the wafer transfer device 1 receives a wafer 2 transferred from the polishing module 4, and the wafer 2 is in a horizontal or approximately horizontal state; and in the second operating state, the wafer transfer device 1 directly turns the wafer 2 from the horizontal or approximately horizontal state to a vertical state, and the wafer 2 in the vertical state is temporarily stored in the box 3 and waits to be transferred to the cleaning module 6 by an external transfer device.

In this embodiment, the polishing module 4 comprises a wafer transfer passage 41, and the wafer transfer device 1 corresponds to the wafer transfer passage 41, that is, a projection of the wafer transfer passage 41 and a projection of the wafer transfer device 1 are located on the same straight line or the projection of the wafer transfer device 1 is located in the wafer transfer passage 41.

The wafer transfer device 1 comprises a back plate 11 and a turning base plate 12 rotatably connected to the back plate 11, and a wafer fixing base 13 used for clamping the wafer 2 is arranged on the turning base plate 12. A spindle 17 is arranged at a lower end of the back plate 11. Of course, in other embodiments, the back plate 11 may be rotatably connected to the turning back plate 12 by means of other structures in the prior art rather than the spindle 17.

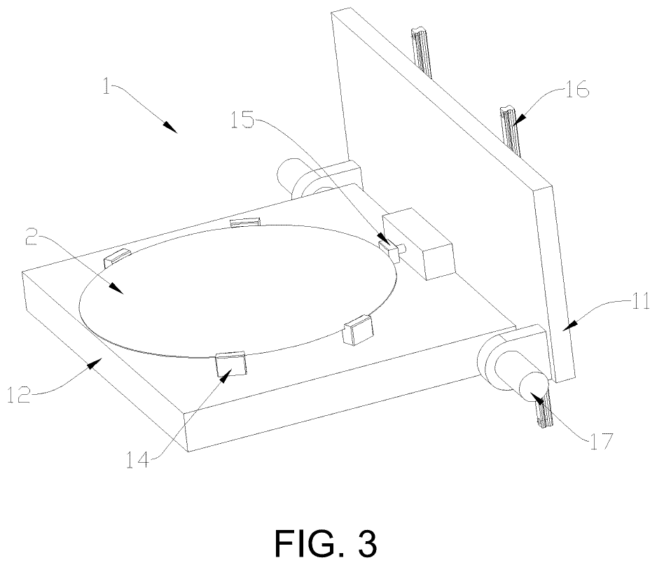

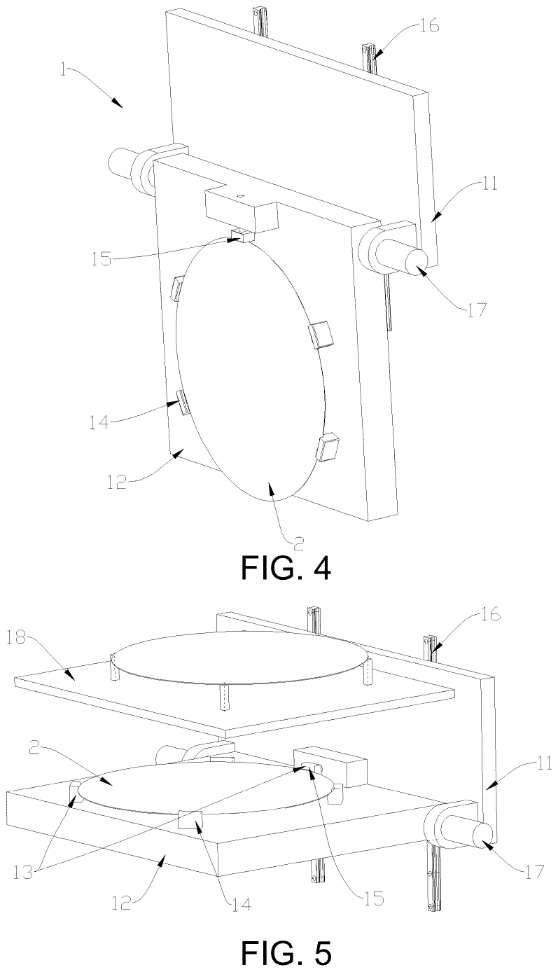

As shown in FIGS. 3 and 4, the first operating state and the second operating state of the wafer transfer device 1 are realized by the turning base plate 12. Specifically, the turning back plate 12 has a first operating state and a second operating state; in the first operating state, an included angle is formed between the turning base plate 12 and the back plate 11, such that the wafer fixing base 13 clamps the wafer 2 horizontally. In this embodiment, the included angle is 90°. Of course, in other embodiments, the included angle may be not 90°, or the wafer fixing base 13 clamps the wafer 2 approximately horizontally.

In the second operating state, the turning base plate 12 rotates with respect to the back plate 11 to switch the wafer 2 to the vertical state, and at this moment, the turning base plate 12 may be parallel to the back plate 11. Here, in the vertical state, the wafer may be not completely perpendicular to the ground and may be approximately perpendicular to the ground.

No matter whether the turning base plate 12 is in the first operating state or the second operating state, the wafer 2 clamped by the wafer fixing base 13 is parallel to the turning back plate 12.

The back plate 11 is able to ascend and descend, and in the second operating state, the turning base plate 12 ascends or descends with the back plate 11. Specifically, the back plate 11 matches slide rails 16, and the slide rails 16 may be mounted at an opening in the top of the box 3.

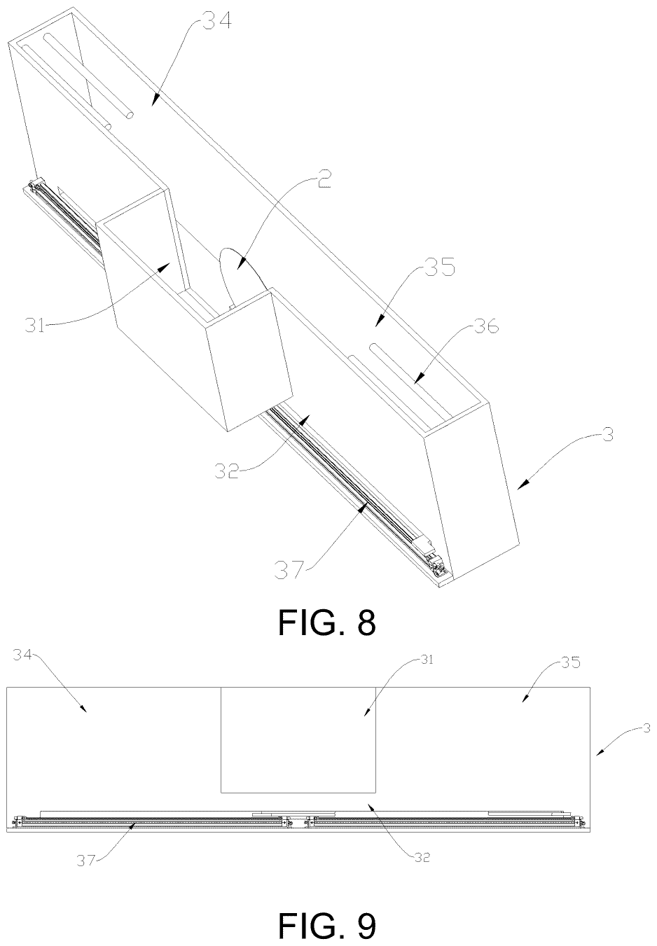

To create a relatively humid environment for the turning base plate 12 in the first operating state, as shown in FIG. 8, the box 3 comprises an upper portion 31 and a lower portion 32, and the upper portion 31 is wider than the lower portion 32. In this way, the turning base plate 12 in the first operating state is located in the upper portion; and when switched from the first operating state to the second operating state, the turning base plate 12 enters the lower portion 32.

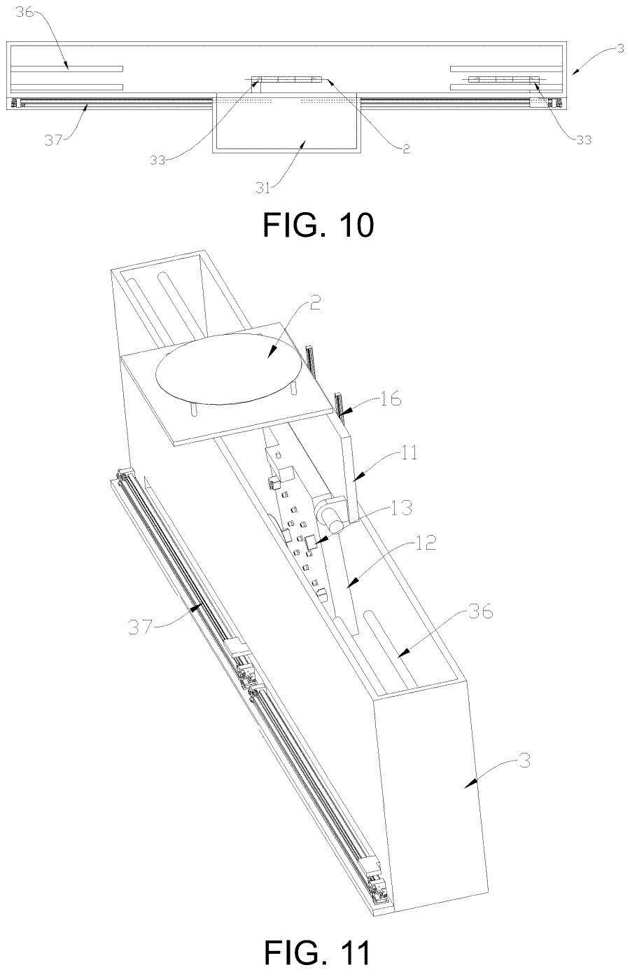

As shown in FIG. 10, one, two or more wafer holders 33 are arranged in the box 3 and used for carrying the wafer 2 in the vertical state from the turning base plate 12. In a case where two wafer holders 33 are arranged in the box 3, one of the wafer holders 33 is used for receiving the wafer 2 from the turning base plate 12, and the other wafer holder 33 stays aside and carries a wafer 2 to be transferred; or, the other wafer holder 33 stays aside and does not carry a wafer. The specific state of the other wafer holder 22 is not limited. The two wafer holders 33 may move synchronously or be controlled separately.

The wafer fixing base 13 comprises at least two support structures 14 and a movable claw 15, wherein the positions of the support structures 14 are fixed relatively, and at least part of the movable claw 15 is movable, such that the movable claw 14 can work together with the support structures 14 to clamp or release the wafer 2.

Here, at least part of the movable claw 15 is movable, which means that at least part of the movable claw 15 is able to telescope or rotate, and the invention has no specific limitation in this aspect.

As shown in FIG. 7, each support structure 14 comprises a body 141 connected to the turning base plate 12, a first oblique surface 142 arranged on the body 141, and a second oblique surface 143 forming a flared opening together with the first oblique surface 142. The first oblique surface 142 inclines from top to bottom and from outside to inside, the wafer 2 is placed on the first oblique surface 142, and the second oblique surface 143 works together with the first oblique surface 142 to clamp the wafer 2, such that upper and lower edges of the wafer 2 respectively come in contact with the second oblique surface 143 and the first oblique surface 142 to reduce the contact area between the support structure 14 and the wafer 2, thus preventing the surface of the wafer 2 from being damaged.

Each support structure 14 further comprises a third oblique surface 144, an included angle is formed between the third oblique surface 144 and the second oblique surface 143, the third oblique surface 144 inclines from top to bottom and from outside to inside, has a large slope, and has a guide effect, and the wafer 2 is guided by the third oblique surface 144 to the space between the first oblique surface 142 and the second oblique surface 143 to be clamped. The first oblique surface 142 and the second oblique surface 143 may be directly connected, or a groove 145 may be formed between the first oblique surface 142 and the second oblique surface 143.

In other words, the wafer 2 can slide onto the first oblique surface 142 along the third oblique surface 144, and then the movable claw 15 telescopes or rotates to press the wafer 2 to move against the first oblique surface 142 and the second oblique surface 143 to a side wall to come in contact with the groove 145 or be close to the groove 145.

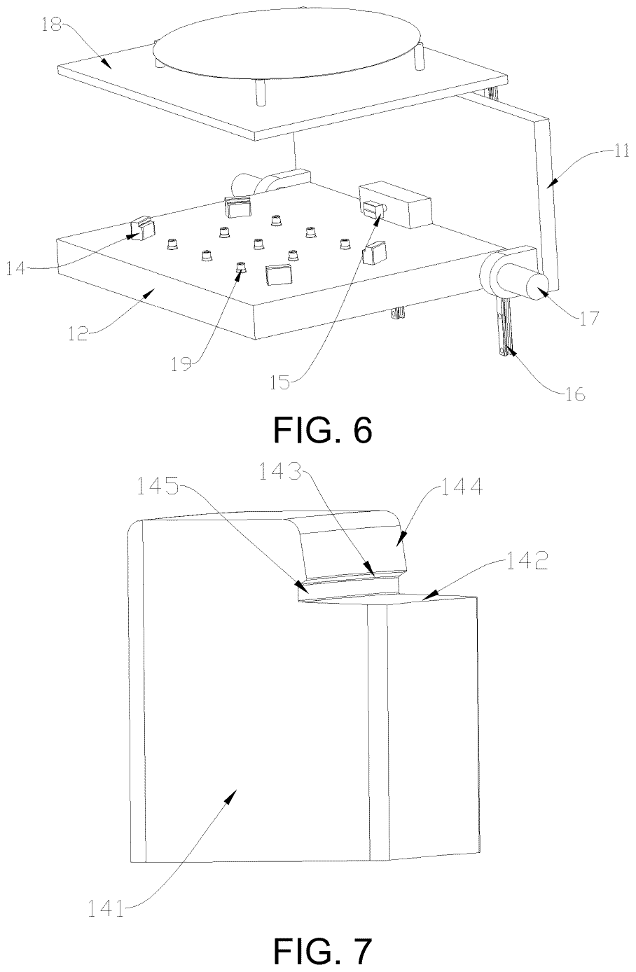

As shown in FIGS. 5 and 6, to improve wafer transfer efficiency, the turning base plate 12 is used for carrying wafers to be cleaned, a support plate 18 located above the turning base plate 12 may be arranged on the back plate 11, the support plate 18 is used for horizontally supporting the wafer 2 to be polished and is designed with a notch or a window that can be opened and closed, and after the wafer 2 on the support plate 18 is transferred away by a robot arm, the notch or window will be uncovered, such that the wafer can be transferred to the turning base plate 12. The notch or window belongs to the prior art and will not be detailed here.

To keep the wafer 2 in a humid condition, nozzles 19 may be arranged on the turning base plate 12, and the nozzles 19 spray pure water to wet the wafer 2 to prevent polishing liquid on the wafer 2 from being evaporated or coagulated, which may otherwise cause damage to the wafer 2.

The wafer 2 is horizontally transferred from the polishing module 4 to the wafer transfer device 1, the turning base plate 12 turns from the first operating state to the second operating state to switch the wafer 2 to the vertical state, wafer 2 is temporarily stored in the box 2 and waits to be transferred to the cleaning module 6 by an external transfer device, and at this moment, the wafer 2 may be transferred in the vertical state to adapt to the cleaning module 6.

The cleaning module 6 comprises at least two rows of cleaning units 61. Each row of cleaning unit 61 comprises multiple cleaning tanks that are arranged at intervals, the box 3 extends towards two sides to form a left portion 34 and right portion 35 corresponding to the cleaning units 61. Because the wafer 2 in the vertical state can move towards the two sides of the box 3, the width of the left portion 34 and the right portion 35 may be approximately the same as the width of the lower portion 32 of the box 3.

Specifically, the wafer holder 22 works together with a slide rail 37 to move the wafer 2 in the vertical state to the left portion 34 or the right portion 35, and spraying mechanisms 36 are arranged at positions corresponding to the left portion 34 and the right portion 35 and can spray liquid to the wafer 2 on the wafer holder 33. In other words, a humid condition in the box 3 can be maintained by liquid in the box 3, and when the turning base plate 12 of the wafer transfer device 1 ascends, descends or rotates in the box 3, the turning base plate 12 is kept in a relatively humid condition to prevent the polishing liquid on the wafer to be cleaned from being evaporated or coagulated to prevent damage to the wafer 2, such that the wafer is protected.

A wafer transfer method is implemented based on the CMP device and comprises the following steps:
the wafer transfer device 1 is in the first operating state, and a wafer 2 polished by the polishing module 4 is transferred to the wafer transfer device 1;
the wafer transfer device 1 directly turns from the first operating state to the second operating state, and the wafer 2 in a vertical state is temporarily stored in box 3; and
the wafer 2 in the vertical state is transferred to the cleaning module 6.

More specifically, the wafer transfer method comprises the following steps:
the turning base plate 12 is in the first operating state, the wafer 1 is horizontally transferred from the polishing module 4 to the wafer fixing base 13, and the wafer fixing base 13 horizontally carries and clamps the wafer 2, wherein at this moment, the turning base plate 12 is located in the box 4, specifically in the upper portion 31 of the box 3; or, at this moment, the turning base plate 12 is close to the opening in the top of the box 3 even if it is not located in the box 3;
the turning base plate 12 rotates with respect to the back plate 11 to the second operating state, that is, the turning base plate 12 turns downwards around the spindle 16 to perpendicular to a bottom surface of the box 3, and at this moment, the wafer 2 is switched to the vertical state;
the back plate 11 descends to drive the turning base plate 12 and the wafer 2 to move downwards to enter the lower portion 32 of the box 3; and
the wafer 2 is horizontally moved by the wafer holder 33 to the left portion 34 or the right portion 35 of the box 3 of the cleaning input module 5, and after the process of the cleaning input module 5 is completed, the wafer 2 in the vertical state is transferred to the cleaning module 6, where after the process of the cleaning input module 5 is completed, the wafer 2 may be in a state of waiting to enter the cleaning module 6, or may be preliminarily cleaned while waiting, for example, the surface of the wafer 2 is washed by the spraying mechanisms 36.

The above specific embodiments are used for explaining the invention, and are not intended to limit the invention. Any modifications and transformations made to the invention based on the spirit of the invention and within the protection scope of the claims should fall within the protection scope of the invention.

1. A CMP device, comprising:
a polishing module;
a cleaning module; and
a cleaning input module, adjacent to the polishing module and the cleaning module and comprising a wafer transfer device;
wherein, the wafer transfer device at least has a first operating state and a second operating state; in the first operating state, the wafer transfer device receives a wafer transferred from the polishing module, and the wafer is in a horizontal or approximately horizontal state; and in the second operating state, the wafer transfer device directly turns the wafer from the horizontal or approximately horizontal state to a vertical state.

2. The CMP device according to claim 1, wherein the cleaning input module further comprises a box, and after being switched to the vertical state, the wafer is temporarily stored in the box to wait to be transferred to the cleaning module by an external transfer device.

3. The CMP device according to claim 1, wherein polishing module comprises a wafer transfer passage, and the wafer transfer device corresponds to the wafer transfer passage.

4. The CMP device according to claim 2, wherein the wafer transfer device comprises:
a back plate; and
a turning base plate, rotatably connected to the back plate and provided with a wafer fixing base for clamping the wafer;
the turning base plate has a first operating state and a second operating state;
in the first operating state, an included angle is formed between the turning base plate and the back plate, and the wafer fixing base clamps the wafer;
in the second operating state, the turning base plate rotates with respect to the back plate to switch the wafer to the vertical state.

5. The CMP device according to claim 4, wherein the back plate is able to ascend and descend along the box, and the box comprises an upper portion and a lower portion; in the first operating state, the turning base plate is located in the upper portion; and when switched from the first operating state to the second operating state, the turning base plate enters the lower portion.

6. The CMP device according to claim 4, wherein one, two or more wafer holders are arranged in the box and used for carrying the wafer in the vertical state from the turning base plate.

7. The CMP device according to claim 4, wherein the wafer fixing base comprises at least two support structures and a movable claw, and at least part of the movable claw is movable to work together with the support structures to clamp or release the wafer.

8. The CMP device according to claim 4, wherein each said support structure comprises a body connected to the turning base plate, a first oblique surface arranged on the body, and a second oblique surface forming a flared opening with the first oblique surface.

9. The CMP device according to claim 8, wherein each said support structure further comprises a third oblique surface, an included angle is formed between the third oblique surface and the second oblique surface, and the wafer is guided by the third oblique surface to a space between the first oblique surface and the second oblique surface to be clamped.

10. The CMP device according to claim 8, wherein groove is formed between the first oblique surface and the second oblique surface.

11. The CMP device according to claim 2, wherein the cleaning module comprises at least two rows of cleaning units, and the box extends towards two sides to form a left portion and a right portion corresponding to the cleaning units.

12. The CMP device according to claim 2, wherein the wafer holder works together with a slide rail to move the wafer in the vertical state to a left portion or a right portion, and spraying mechanisms are arranged in the box.

13. A wafer transfer method for the CMP device according to claim comprising the following steps:
keeping the wafer transfer device in the first operating state, and transferring a wafer from the polishing module to the wafer transfer device;
directly turning the wafer transfer device from the first operating state to the second operating state, and temporarily storing the wafer in a vertical state in the box; and
transferring the wafer in the vertical state to the cleaning module.

14. The wafer transfer method according to claim 13, comprising the following steps:
keeping the turning base plate in the first operating state, and horizontally carrying and clamping the wafer by the wafer fixing base;
rotating the turning base plate with respect to the back plate to the second operating state to switch the wafer to the vertical state; and
allowing the back plate to descend drive the turning base plate and the wafer to descend.

15. The wafer transfer method according to claim 13, comprising the following steps:
keeping the turning base plate in the first operating state, horizontally transferring the wafer from the polishing module to the wafer fixing base, and clamping the wafer by the wafer fixing base, wherein the turning base plate is located in the box at this moment;
rotating the turning base plate with respect to the back plate to the second operating state to switch the wafer to the vertical state;
allowing the back plate to descend drive the turning base plate and the wafer to descend; and
transferring the wafer in the vertical state to the cleaning module.

16. The wafer transfer method according to claim 15, wherein in the step of transferring the wafer in the vertical state to the cleaning module,
after a process of the cleaning input module is completed, the wafer is horizontally moved to the left portion or the right portion of the box and then transferred to the cleaning module in the vertical state.
